(19) United States
(12) Patent Application Publication
(10) Pub. No.: US 2013/0083567 A1
(43) Pub. Date: Apr. 4, 2013

(54) COMPOUND SEMICONDUCTOR DEVICE AND METHOD FOR FABRICATING THE SAME

(71) Applicant: Tadahiro Imada, Kawasaki (JP)

(72) Inventor: Tadahiro Imada, Kawasaki (JP)

(73) Assignee: FUJITSU LIMITED, Kawasaki-shi (JP)

(21) Appl. No.: 13/551,769

(22) Filed: Jul. 18, 2012

(30) Foreign Application Priority Data
Sep. 29, 2011 (JP) 2011-214723

(51) Int. Cl. H01L 29/772; H02M 5/458; H01L 21/20

(52) U.S. Cl. 363/37; 257/192; 438/478; 257/E29.242; 257/E21.09

(57) ABSTRACT

A compound semiconductor device includes an electron transit layer having a first polarity, a p-type cap layer which is formed above the electron transit layer and has a second polarity, and an n-type cap layer which is formed on the p-type cap layer and has the first polarity. The n-type cap layer includes portions having different thicknesses.

### CROSS-REFERENCE TO RELATED APPLICATION

This application is based upon and claims the benefit of priority of the prior Japanese Patent Application No. 2011-214723, filed on Sep. 29, 2011, the entire contents of which are incorporated herein by reference.

### FIELD

The present embodiments relate to compound semiconductor device and a method for fabricating the compound semiconductor device.

### BACKGROUND

Nitride semiconductors have high saturated electron velocities and wide bandgaps. Taking advantage of these and other characteristics, application of the nitride semiconductors to high-withstand-voltage and high-output semiconductor devices has been studied. For example, GaN, which is a nitride semiconductor, has a bandgap of 3.4 eV, which is higher than the bandgaps of Si (1.1 eV) and GaAs (1.4 eV), and has a higher breakdown field strength. For this reason, GaN holds great promise as a material of power-supply semiconductor devices that provide high-voltage operation and high output.

For nitride-semiconductor-based devices, many reports on nitride-semiconductor-based field-effect transistors, especially High Electron Mobility Transistors (HEMTs), have been made. For example, research on GaN-based HEMTs (GaN-HEMTs) has focused on AlGaN/GaN HEMTs that use GaN for an electron transit layer and AlGaN for an electron donor layer. In the AlGaN/GaN HEMTs, strain in AlGaN is caused by the difference in grating constant between GaN and AlGaN. Piezoelectric polarization and AlGaN spontaneous polarization caused by the strain provide a high-concentration two-dimensional electron gas (2DEG), which makes AlGaN/GaN HEMTs desirable for use as high-efficiency switch elements and high-withstand-voltage power devices for electric vehicles.

Patent Document 1: Japanese Laid-Open Patent Publication No. 2007-220895

There are demands for a technique to locally control the amount of 2DEG produced in nitride semiconductor devices. For example, the so-called normally-off operation in which no current flows in the absence of voltage is desired in HEMTs in terms of fail-safe. To achieve this, a scheme to minimize the amount of 2DEG production under a gate electrode in the absence of voltage is needed.

One approach to implementing a normally-off GaN HEMT has been proposed in which a p-type GaN layer is formed on an electron donor layer to control the concentration of 2DEG by a band modulation effect.

However, manufacturing technology for GaN is less developed than that for the Si, which has a long technological history. Therefore it is difficult to optimize the p-type GaN structure. For example, in the case of Si, a sophisticated ion implantation technology can be used to fabricate a super junction structure that includes a vertically long p-type ion implantation layer, whereas for GaN, ion implantation technologies for GaN itself are immature.

In the field of RF, on the other hand, GaN-HEMTs have already been put in to practical use. Therefore, there is a strong demand from the semiconductor market to solve the problem described above without waiting until manufacturing technologies such as ion implantation reach maturity and Si device structures become available.

### SUMMARY

One mode of a compound semiconductor device includes a first compound semiconductor layer having a first polarity, a second compound semiconductor layer which is formed above the first compound semiconductor layer and has a second polarity, and
a third compound semiconductor formed above the second compound semiconductor layer, the third compound semiconductor layer having the first polarity. The third compound semiconductor layer includes a portion having a different thickness.

One mode of a method for fabricating a compound semiconductor device involves forming a first compound semiconductor layer having a first polarity, forming a second compound semiconductor layer above the first compound semiconductor layer which has a second polarity, forming a third compound semiconductor layer above the second compound semiconductor layer, the third compound semiconductor layer having the second polarity, and forming a portion having a different thickness in the third compound semiconductor layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a schematic cross-sectional view illustrating step by step a method for fabricating an AlGaN/GaN HEMT according to a first embodiment;

FIG. 2 is a schematic cross-sectional view continued from FIG. 1 illustrating step by step the method for fabricating the AlGaN/GaN HEMT according to the first embodiment;

FIG. 3 is a schematic cross-sectional view continued from FIG. 2 illustrating step by step the method for fabricating the AlGaN/GaN HEMT according to the first embodiment;

FIG. 4 is a schematic plan view illustrating a configuration of the AlGaN/GaN HEMT according to the first embodiment;

FIG. 5 is a characteristics diagram illustrating the results of an investigation of the relationship between drain-source voltage Vds and drain current Id in the first embodiment;

FIG. 6 is a characteristics diagram illustrating the results of an investigation of the time that elapsed before breakdown after continuous application of voltage Vds between the source and the drain;

FIG. 7 is a characteristics diagram illustrating the results of an investigation of the concentration of 2DEG during non-operation;

FIG. 8 is a schematic plan view of an HEMT chip using an AlGaN/GaN HEMT according to the first embodiment;

FIG. 9 is a schematic plan view of a discrete package using an AlGaN/GaN HEMT according to the first embodiment;

FIG. 10 is a schematic cross-sectional view illustrating principal steps of a method for fabricating an AlGaN/GaN diode according to a second embodiment;

FIG. 11 is a schematic cross-sectional view continued from FIG. 10 illustrating principal steps of the method for fabricating the AlGaN/GaN diode according to the second embodiment;

FIG. 12 is a cross-sectional view continued from FIG. 11 illustrating principal steps of the method for fabricating the AlGaN/GaN diode according to the second embodiment;

FIG. 13 is a characteristics diagram illustrating the results of an investigation of the relationship between anode-cathode voltage Vac and anode current Ia in the second embodiment;

FIG. 14 is a characteristics diagram illustrating the results of an investigation of the time that elapsed before breakdown after continuous application of a reverse voltage between the anode and the cathode;

FIG. 15 is a schematic plan view of a diode chip using an AlGaN/GaN diode according to the second embodiment;

FIG. 16 is a schematic plan view of a discrete package using an AlGaN/GaN diode according to the second embodiment;

FIG. 17 is a connection diagram of a PFC circuit according to a third embodiment;

FIG. 18 is a connection diagram schematically illustrating a configuration of a power supply device according to a fourth embodiment; and

FIG. 19 is a connection diagram schematically illustrating a configuration of a high-frequency amplifier according to a fifth embodiment.

### DESCRIPTION OF EMBODIMENTS

Embodiments will be described below in detail with reference to diagrams. Configurations of compound semiconductor devices will be described in conjunction with methods for fabricating the devices in the embodiments below.

It is noted that for convenience of illustration, the sizes and thicknesses of some of the components in the drawings are not depicted to scale.

### First Embodiment

In a first embodiment, an AlGaN/GaN HEMT will be disclosed as a compound semiconductor device.

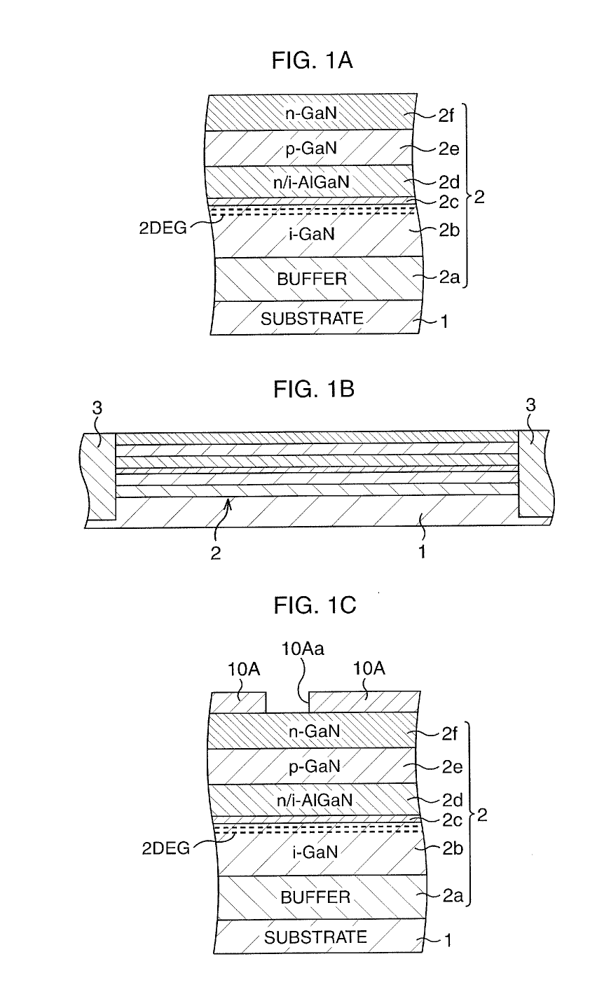

FIGS. 1 to 3 are schematic cross-sectional views illustrating step by step a method for fabricating an AlGaN/GaN HEMT according to the first embodiment.

As illustrated in FIG. 1A, first a compound semiconductor multilayer structure 2 is formed on a growth substrate, for example a Si substrate 1. The growth substrate may be of other material such as a sapphire substrate, a GaAs substrate, a SiC substrate, or a GaN substrate instead of Si substrate. The substrate may be a semi-insulating substrate or a conductive substrate.

The compound semiconductor multilayer structure 2 includes a buffer layer 2a, an electron transit layer 2b, an intermediate layer (spacer layer) 2c, an electron donor layer 2d, p-type cap layer 2e, and an n-type cap layer 2f. Here, the electron transit layer 2b has a negative polarity so that two-dimensional electron gas is produced at the interface with the intermediate layer 2c as will be described later. Similarly, the n-type cap layer 2f has also a negative polarity so that the conductivity type of the n-type cap layer 2f has the n-type. On the other hand, the p-type cap layer 2e has a positive polarity because the p-type cap layer 2e is opposite in conductivity type to the n-type.

Specifically, the following compound semiconductors are grown on the Si substrate 1 by Metal Organic Vapor Phase Epitaxy (MOVPE), for example. Other method such as Molecular Beam Epitaxy (MBE) may be used instead of MOVPE.

Compound semiconductors that will serve as the buffer layer 2a, electron transit layer 2b, the intermediate layer 2c, the electron donor layer 2d, the p-type cap layer 2e, and the n-type cap layer 2f are grown on the Si substrate 1 in that order. The buffer layer 2a is formed by growing AlN on the Si substrate 1 to a thickness of approximately 0.1 μm. The electron transit layer 2b is formed by growing i (intentionally undoped)-GaN to a thickness in the range of approximately 1 μm to approximately 3 μm. The intermediate layer 2c is formed by growing i-AlGaN to a thickness of approximately 5 nm. The donor layer 2d is formed by growing n-AlGaN to a thickness of approximately 30 nm. The intermediate layer 2c may be omitted. The electron donor layer may be formed of i-AlGaN.

The p-type cap layer 2e is formed by growing p-GaN to a thickness in the range of approximately 10 nm to approximately 1000 nm, for example. If the p-type cap layer 2e is thinner than 10 nm, a desired normally-off operation cannot be achieved; if the p-type cap layer 2e is thicker than 1000 nm, the distance from a gate electrode to the AlGaN/GaN hetero interface, which acts as a channel, will be long so that response speed will decrease and electric fields from the gate electrode in the channel will be insufficient, thereby causing defects such as poor pinch-off. Therefore, the p-type cap layer 2e is formed to a thickness in the range of approximately 10 nm to approximately 1000 nm to ensure high response speed and prevent degradation of the device characteristics, such as poor pinch-off while achieving a proper normally-off operation. In this embodiment, p-GaN of the p-type cap layer 2e is formed to a thickness of approximately 200 nm.

The n-type cap layer 2f is formed by growing n-GaN to a thickness in the range of approximately 5 nm to approximately 500 nm, for example, here, to a thickness of approximately 100 nm, by taking into consideration the thickness of the p-type cap layer 2e.

To grow GaN, mixed gas of trimethyl gallium (TMGa) gas, which is the Ga source, and ammonium (NH₃) gas is used as material gas. To grow AlGaN, mixed gas of TMAl gas, TMGa gas and NH₃ gas is used as the material gas. Supplying and discontinuing supplying the TMAl and TMGa gases and the flow rates of the TMAl and TMGa gases are set as appropriate according to the compound semiconductor layer to grow. The flow rate of the NH₃ gas, which is a material common to the layers, is set to a value in the range of approximately 100 sccm to approximately 10 slm. The growth pressure is set to a value in the range of approximately 50 Torr to 300 Torr and the growth temperature is set to a value in the range of approximately 1000° C. to 1200° C.

When AlGaN and GaN are grown as the n-type, that is, when the electron donor layer 2d (n-AlGaN) and the n-type cap layer 2f (n-GaN) are formed, an n-type impurity is added to the material gasses of AlGaN and GaN. Here, for example silane (SiH₄) gas containing Si for example is added at a predetermined flow rate to the material gasses to dope AlGaN and GaN with Si. The doping concentration of Si is set to a value in the range of approximately 1×10¹⁸/cm³ to approximately 1×10²⁰/cm³, for example approximately 2×10¹⁸/cm³.

When GaN is grown as the p-type, that is, when the p-type cap layer 2e (p-GaN) is formed, a p-type impurity, for example an impurity selected between Mg and C, is added to the material gas of GaN. In this embodiment, Mg is used as the p-type impurity. Mg is added at a predetermined flow rate to the material gas to dope GaN with Mg. The doping concentration of Mg is in the range of approximately 1×10¹⁶/cm³ to approximately 1×10²¹/cm³, for example. If the doping concentration is less than approximately 1×10¹⁶/cm³, GaN is not sufficiently doped to p-type and the p-type cap layer 2e will be normally on; if the doping concentration is greater than approximately 1×10²¹/cm³, imperfect crystallinity may result and sufficiently good characteristics cannot be provided. By choosing a Mg doping concentration in the range of approximately 1×10¹⁶/cm³ to approximately 1×10²¹/cm³, a p-type semiconductor that provides sufficiently good normally-off characteristics can be produced. In this embodiment, the Mg doping concentration in the p-type cap layer 2e is approximately 1×10¹⁹/cm³.

In the compound semiconductor multilayer structure 2 thus formed, piezoelectric polarization is caused at the interface of the electron transit layer 2b having the negative polarity with the electron donor layer 2d (to be exact, the interface with the intermediate layer 2c, which will be hereinafter referred to as the GaN/AlGaN interface) by a distortion due to the difference in lattice constant between GaN and AlGaN. The effect of the piezoelectric polarization in combination with the effect of spontaneous polarization in the electron transit layer 2b and the electron donor layer 2d produces two-dimensional electron gas (2DEG) with a high electron concentration at the GaN/AlGaN interface.

After the compound semiconductor multilayer structure 2 has been formed, the p-type cap layer 2e is annealed at approximately 700° C. for approximately 30 minutes.

An element isolating structure 3 is formed as illustrated in FIG. 1B. The element isolating structure 3 is omitted from FIG. 1C and the subsequent drawings.

Specifically, argon (Ar), for example, is injected into the element isolating region of the compound semiconductor multilayer structure 2. As a result, the element isolating structure 3 is formed in the compound semiconductor multilayer structure 2 and a surface portion of the Si substrate 1. An active region is defined on the compound semiconductor multilayer structure 2 by the element isolating structure 3.

It is noted that element isolation may be made by other known method such as Shallow Trench Isolation (STI), for example, instead of the injection method described above. Here, chlorine-based etching gas, for example, is used for dry etching of the compound semiconductor multilayer structure 2.

Then, as illustrated in FIGS. 1C to 3A, the n-type cap layer 2f is etched into a desired shape.

Specifically, as illustrated in FIG. 1C, first a resist is applied on the n-type cap layer 2f and lithography is used to process the n-type cap layer 2f. This forms a resist mask 10A having an opening 10Aa that exposes a region on the surface of the n-type cap layer 2f where a gate electrode is to be formed.

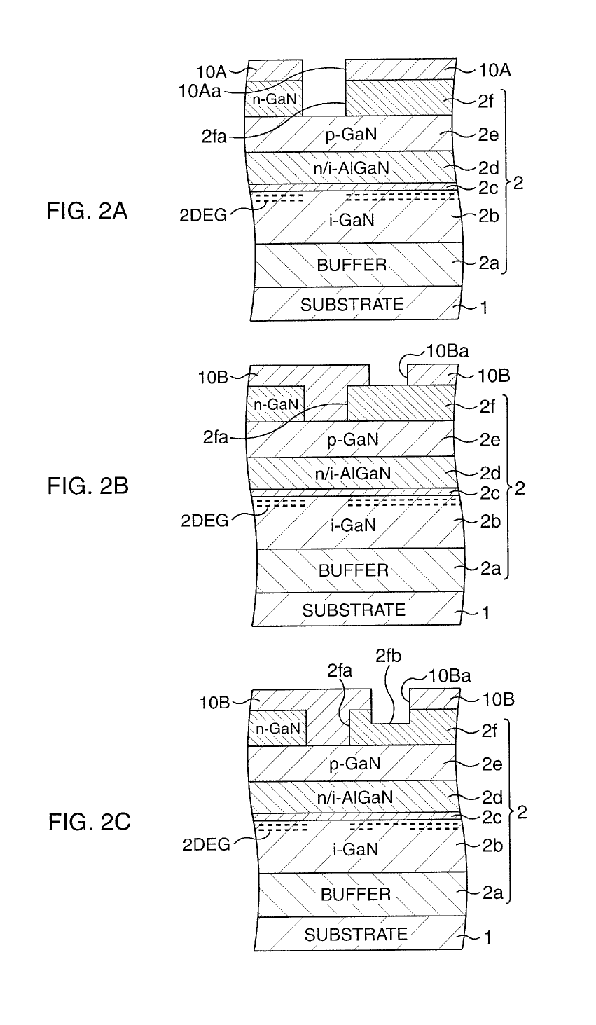

Then, as illustrated in FIG. 2A, the resist mask 10A is used to etch the n-type cap layer 2f by reactive ion etching (RIE) with Cl₂ as the etching gas. As a result, an opening 2fa that exposes a region on the surface of the p-type cap layer 2e where the gate electrode is to be formed is formed in the n-type cap layer 2f. The opening 2fa is formed in a predetermined location closer to a location where a source electrode is to be formed than a location where a drain electrode is to be formed.

The resist mask 10A is then removed by ashing or a wet process with a predetermined chemical.

In the compound semiconductor multilayer structure 2 in which the opening 2fa is formed in the n-type cap layer 2f, n-GaN of the n-type cap layer 2f does not exist in the opening 2fa. Accordingly, 2DEG in the region at the GaN/AlGaN interface that is located under the opening 2fa is almost depleted by p-GaN of the p-type cap layer 2e. The example depicted illustrates that 2DEG has been depleted.

Then, a resist is applied on the n-type cap layer 2f so that the resist fills the opening 2fa, and is then processed by lithography as illustrated in FIG. 2B. This forms a resist mask 10B having an opening 10Ba that exposes a region of the surface of the n-type cap layer 2f where a filed-plate electrode is to be formed.

Then, the resist mask 10B is used to etch the n-type cap layer 2f by RIE using Cl₂ gas as the etching gas, as illustrated in FIG. 2C. In this way, the region in the n-type cap layer 2f where the field-plate electrode is to be formed is thinned to a desired thickness. The thinned portion 2fb is formed in a predetermined region that is located between the opening 2fa and the location where the drain electrode is to be formed and is closer to the location where the drain electrode is to be formed than the location where the source electrode is to be formed. The thickness of the thinned portion 2fb is about the half of the thickness of the n-type cap layer 2f, for example approximately 50 nm, by taking into consideration desired control of the amount of 2DEG by the field-plate electrode. It is noted that the thinning of the n-type cap layer 2f may be omitted if the compound semiconductor device is used only as a diode, for example.

In the compound semiconductor multilayer structure 2 in which the thinned portion 2fb is formed in the n-type cap layer 2f, n-GaN of the thinned portion 2fb is thinner than the rest of the n-type cap layer 2f (excluding the opening 2fa). Accordingly, 2DEG in the portion of the GaN/AlGaN interface that is located under the thinned portion 2fb is reduced by p-GaN of the p-type cap layer 2e by an amount according to the thinness of the thinned portion 2fb, as depicted.

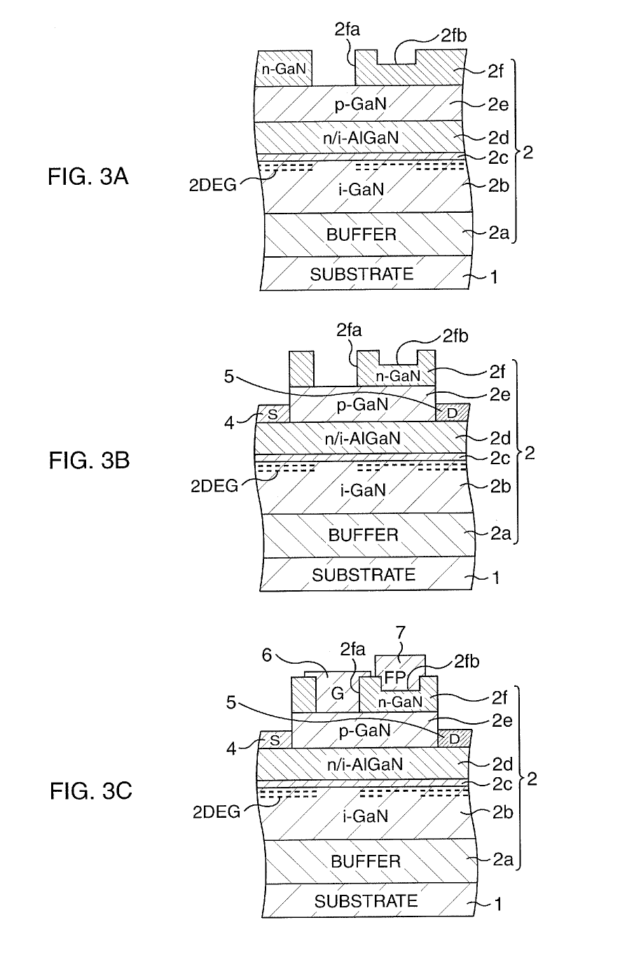

The resist mask 10B is then removed by ashing or a wet process with a predetermined chemical as illustrated in FIG. 3A. As a result, the n-type cap layer 2f is exposed with the openings 2fa and 2fb formed.

Then, a source electrode 4 and a drain electrode 5 are formed as illustrated in FIG. 3B.

Specifically, first recesses 2A and 2B for the electrodes are formed in regions of the surface of the compound semiconductor multilayer structure 2 where the source electrode and the drain electrode are to be formed (electrode formation regions).

A resist is applied on the surface of the compound semiconductor multilayer structure 2. The resist is processed by lithography to form openings that expose the electrode formation regions of the surface of the compound semiconductor multilayer structure 2. In this way, a resist mask having the openings is formed.

The resist mask is used to dry-etch the electrode formation regions of the n-type cap layer 2f and the p-type cap layer 2e to remove the n-type and p-type cap layers 2e from the electrode formation regions until the surface of the electron donor layer 2d is exposed. As a result, the electrode recesses 2A and 2B that expose the surface of the electron formation regions of the electron donor layer 2d are formed. The etching is performed using an inactive gas such as Ar and a chlorine-based gas such as Cl₂ as etch gasses. For example, Cl₂ is injected at a flow rate of 30 sccm and a pressure of 2 Pa with an RF input power of 20 W. The electrode recesses 2A and 2B may be formed by etching into the electron donor layer 2d and deeper.

The resist mask is then removed by ashing or a wet process with a predetermined chemical.

A resist mask for forming the source electrode and the drain electrodes is formed. Here, for example an overhanging double layer resist, which is suitable for vapor deposition and lift-off, is used. The resist is applied on the compound semiconductor multilayer structure 2 and openings exposing the electrode recesses 2A and 2B are formed. In this way, a resist mask having the opening is formed.

An electrode material, for example Ta/Al is deposited on the resist mask, including the regions inside the openings exposing the electrode recesses 2A and 2B, by vapor deposition, for example. Ta is deposited to a thickness of approximately 20 nm; Al is deposited to a thickness of approximately 200 nm. The resist mask and the Ta/Al deposited on the resist mask are removed by lift-off. Thereafter, the Si substrate 1 is heat-treated in a nitrogen atmosphere, for example, at a temperature in the range of 400° C. to 1000° C., for example approximately 600° C. to bring the remaining Ta/Al into ohmic contact with the electron donor layer 2d. The heat treatment may be omitted if ohmic contact between Ta/Al and the electron donor layer 2d can be made without the heat treatment. In this way, the electrode recesses 2A and 2B are filled with part of the electrode material to form the source electrode 4 and the drain electrode 5.

Then, a gate electrode 6 and a field-plate electrode 7 are formed as illustrated in FIG. 3C.

Specifically, first a resist mask for forming the gate electrode and the field electrode is formed. Here, for example an overhanging double layer resist, which is suitable for vapor deposition and lift-off, is used. The resist is applied on the compound semiconductor multilayer structure 2 and openings exposing the opening 2fa and the thinned portion 2fb are formed. In this way, a resist mask having the opening is formed.

An electrode material, for example Ni/Au is deposited on the resist mask, including the regions inside the openings exposing the opening 2fa and the thinned portion 2fb of the n-type cap layer 2f. Ni is deposited to a thickness of approximately 30 nm; Au is deposited to a thickness of approximately 400 nm. The resist mask and Ni/Au deposited on the resist mask are removed by lift-off. In this way, the opening 2fa of the n-type cap layer 2f is filled with part of the electrode material to form the gate electrode 6 and the recess on the thinned portion 2fb of the n-type cap layer 2f is filled with part of the electrode material to form the field-plate electrode 7.

The field-plate electrode 7 is formed in a location between the gate electrode 6 and the drain electrode 5 closer to the drain electrode 5 than the source electrode 4. In an AlGaN/GaN HEMT, a higher voltage is applied to a drain electrode than the voltages applied to source and gate electrodes in some cases. In the present configuration, an electric field produced by application of a high voltage can be reduced by the field-plate electrode 7.

Thereafter, steps such as the steps of electrically connecting the source electrode 4, the drain electrode 5, and the gate electrode 6 and forming pads for the source electrode 4, the drain electrode 5, and the gate electrode 6 are performed to complete an AlGaN/GaN HEMT according to this embodiment.

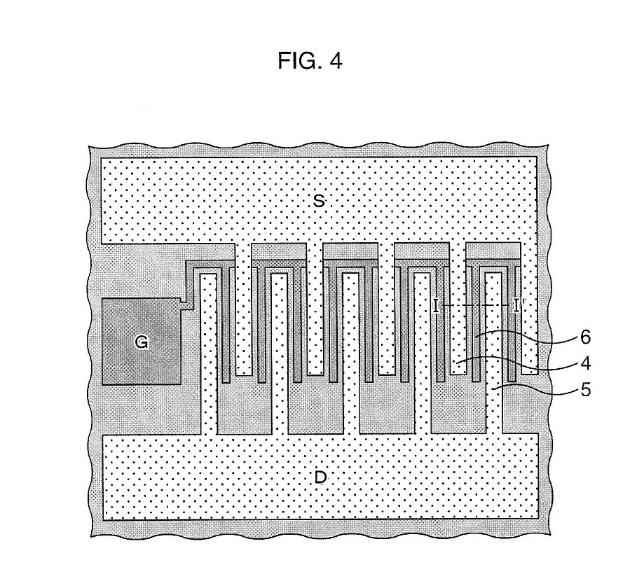

FIG. 4 is a plan view of the AlGaN/GaN HEMT according to this embodiment.

The cross section taken along dashed line I-I′ in FIG. 4 is the cross-sectional view of FIG. 3C. In this way, the source electrode 4 and the drain electrode 5 are formed parallel to each other like comb teeth and the comb-tooth-like gate electrode 6 is disposed between and parallel with the source electrode 4 and the drain electrode 5.

While the AlGaN/GaN HEMT of Schottky type in which the gate electrode is in direct contact with the compound semiconductor has been described as an example of this embodiment, the present embodiment can be applied to an AlGaN/GaN HEMT of MIS type as well in which a gate insulating film is provided between a gate electrode and a compound semiconductor. To fabricate an AlGaN/GaN HEMT of MIS type, a gate insulating film is formed on the n-type cap layer 2f in such a manner that the gate insulting film covers the sidewalls of the opening 2fa after the step of FIG. 2(a), and the gate insulating film is bored and the thinned portion 2fb is formed in the step of FIG. 2C. Then, a gate electrode and a field-plate electrode are formed in the step of FIG. 3C.

In the AlGaN/GaN HEMT according to this embodiment, the n-type cap layer 2f on the p-type cap layer 2e is appropriately etched to control the concentration of 2DEG while the p-type cap layer 2e is left intact without etching the cap layer of p-GaN or regrowing p-GaN. In this way, the thickness of the n-type cap layer 2f is adjusted to effectively control the concentration of the p-type impurity (here, Mg) of the p-type cap layer 2e, thereby allowing the filed-plate electrode 7 to easily and reliably control the concentration of 2DEG while achieving a desired normally-off operation. That is, when the gate voltage is off, there is not 2DEG in the channel and therefore the normally-off state is achieved; when the gate voltage is on, desired 2DEG is produced in the channel to drive.

Under the field-plate electrode 7, p-GaN of the p-type cap layer 2e and n-AlGaN of the electron donor layer 2d form a p-n junction. The p-type cap layer 2e is in a depletion state in relation to n-type cap layer 2f and thus the depletion layer is extended. This significantly improve the withstand voltage and significantly reduces parasitic capacitances Cds and Cgd to increase the operation speed of the device.

Furthermore, in this embodiment, the p-n junction of the p-type cap layer 2e and the electron donor layer 2d under the field-plate electrode 7 forms a p-n junction to provide the function of a protection diode in which the field-plate electrode 7 serves as the anode and the drain electrode 5 serves as the cathode. The rectification effect of the protection diode prevents breakdown of the AlGaN/GaN HEMT if a surge voltage is generated in the AlGaN/GaN HEMT. In this way, sufficient avalanche resistance is ensured to contribute to stabilization of device operations.

Experiments conducted for investigating characteristics of the AlGaN/GaN HEMT according to this embodiment will be described below. As a comparative example, an AlGaN/GaN HEMT fabricated by growing p-GaN on an n-type cap layer of n-GaN, etching off unnecessary parts of p-GaN, then regrowing p-GaN with a different Mg concentration and performing whole thermal annealing is given.

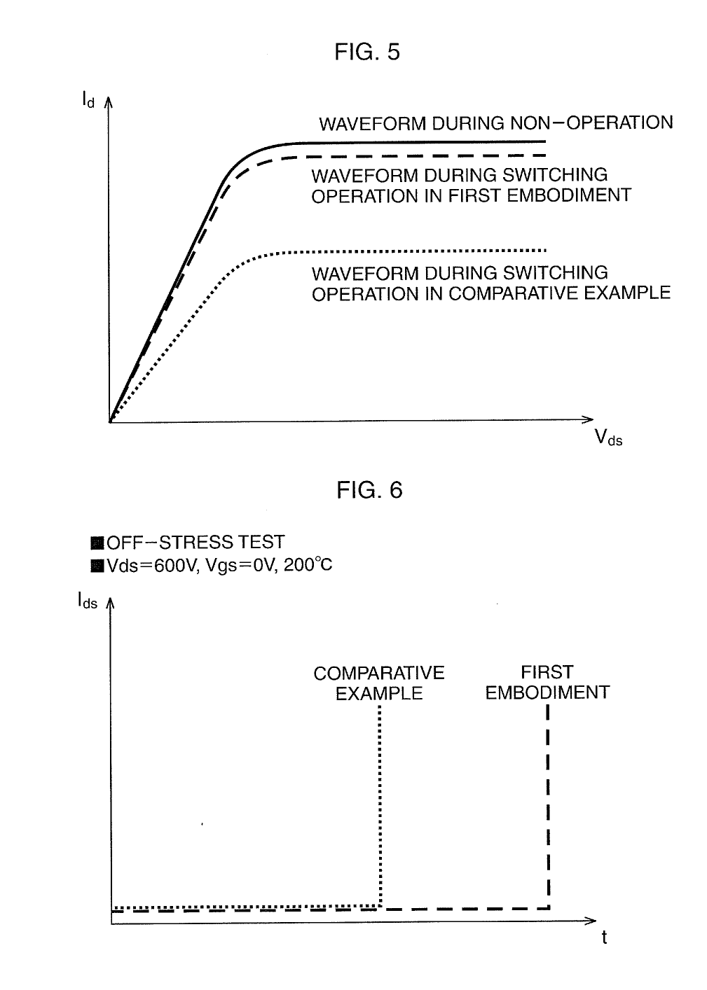

In experiment 1, the relationship between source-drain voltage Vds and drain current Id was studied. The results of the experiment are given in FIG. 5. In contrast to the comparative example, this embodiment shows a waveform during operation that is not much different from a waveform during non-operation. The results demonstrate that the present embodiment achieves a significant improvement in preventing reduction in current during operation as compared with the comparative example.

In experiment 2, drain-source voltage Vds was continuously applied to determine the time that elapsed before breakdown (off-stress test). Here, Vds of 600 V was applied at a temperature of 200° C. and the gate-source voltage Vgs was set to 0 V. FIG. 6 gives the results of the experiment. The results demonstrate that the time for breakdown to occur increases and the reliability of the device is improved in this embodiment as compared with the comparative example.

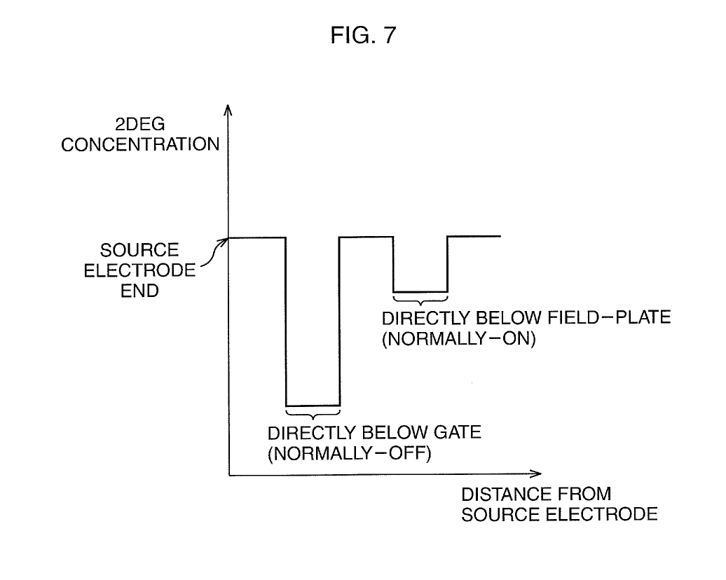

In experiment 3, the concentration of 2DEG in the AlGaN/GaN HEMT according to the present embodiment during non-operation was investigated. The results of the experiment are given in FIG. 7. In this embodiment, the concentration of 2DEG in the region under the gate electrode is sufficiently low and a normally-off operation is achieved. It can be seen that the concentration of 2DEG in the region under the field-plate electrode is modulated to a desired value.

As has been described above, this embodiment implements a reliable, a high-withstand-voltage AlGaN/GaN HEMT in which the p-type cap layer 2e is used with the n-type cap layer 2f to minimize an increase in the on-state resistance during operation and not to regrow p-GaN during fabrication and the doping dose of the p-type impurity is in effect easily and reliably controlled to a predetermined value to enable a complex operation.

The AlGaN/GaN HEMT according to this embodiment is applicable to the so-called discrete package.

An AlGaN/GaN HEMT chip according to this embodiment is mounted on the discrete package. The discrete package of the AlGaN/GaN HEMT chip according to this embodiment (hereinafter referred to as the HEMT chip) will be described below.

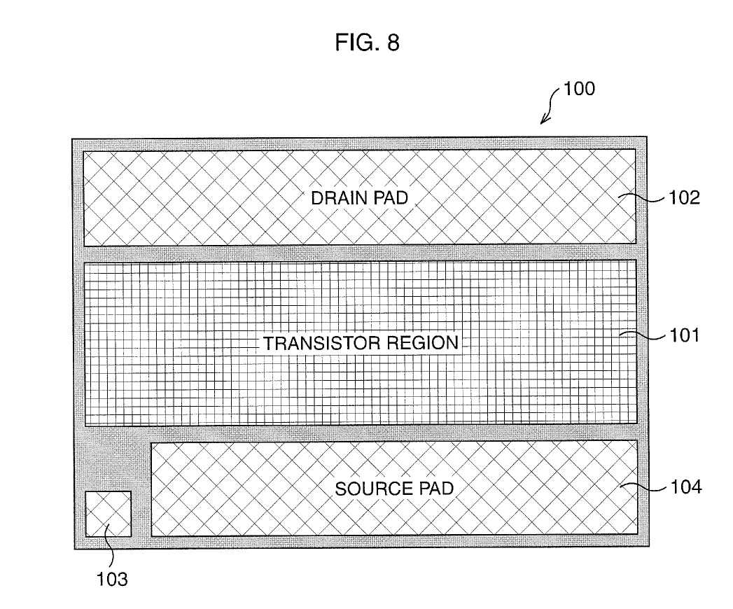

FIG. 8 schematically illustrates a configuration of the HEMT chip (corresponding to FIG. 4).

A transistor region 101 of the AlGaN/GaN HEMT described above, a drain pad 102 to which drain electrodes are connected, a gate pad 103 to which gate electrodes are connected, and a source pad 104 to which source electrodes are connected are provided on a surface of the HEMT chip 100.

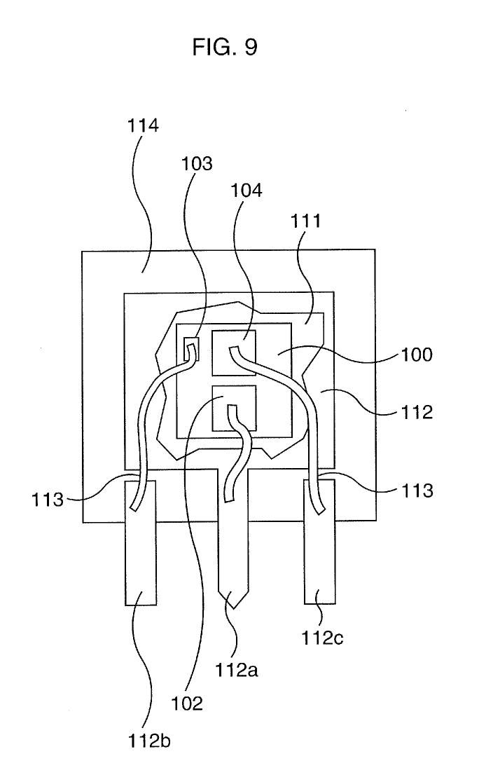

FIG. 9 is a schematic plan view of the discrete package.

To fabricate the discrete package, first the HEMT chip 100 is fixed to a lead frame 112 with a die attach paste 111 such as solder. A drain lead 112a is formed monolithically with the lead frame 112 and a gate lead 112b and a source lead 112c are disposed separately and spaced apart from the lead frame 112.

Then, bonding with Al wires 113 is performed to electrically connect the drain pad 102 with the drain lead 112a, the gate pad 103 with the gate lead 112b, and the source pad 104 with the source lead 112c.

Thereafter, using a mold resin 114 the HEMT chip 100 is encapsulated with resin by transfer molding and the lead frame 112 is cut off. Thus, a discrete package is completed.

### Second Embodiment

In a second embodiment, an AlGaN/GaN high electron mobility diode (hereinafter simply referred to as the AlGaN/GaN diode) will be disclosed as a compound semiconductor device.

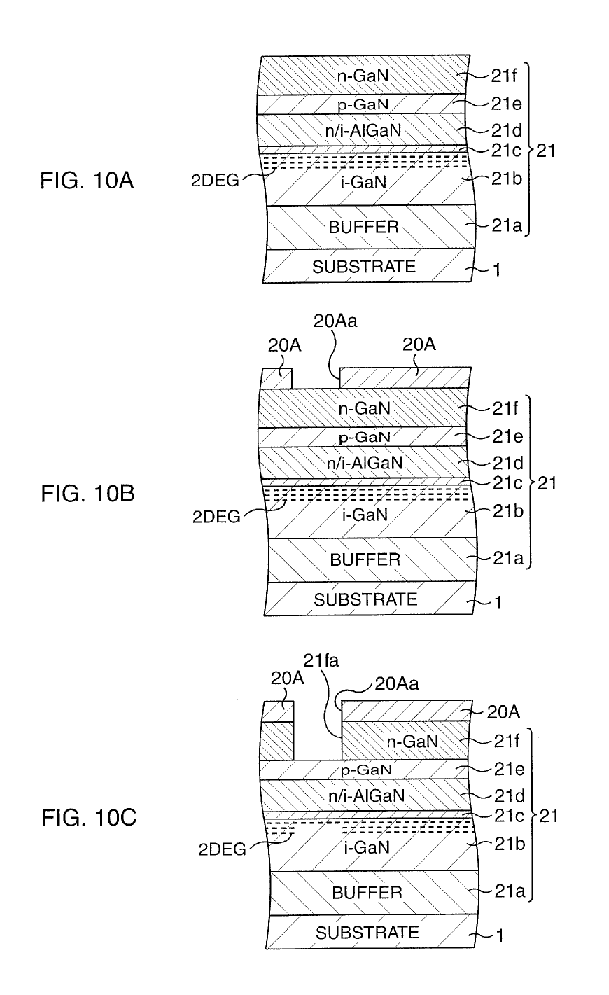

FIGS. 10 to 12 are schematic cross-sectional views illustrating step by step a method for fabricating an AlGaN/GaN diode according to the second embodiment.

As illustrated in FIG. 10A, first a compound semiconductor multilayer structure 21 is formed on a growth substrate, for example a Si substrate 1. The growth substrate may be of other material such as a sapphire substrate, a GaAs substrate, a SiC substrate, or a GaN substrate. The substrate may be a semi-insulating substrate or a conductive substrate.

The compound semiconductor multilayer structure includes a buffer layer 21a, an electron transit layer 21b, an intermediate layer (spacer layer) 21c, an electron donor layer 21d, p-type cap layer 21e, and an n-type cap layer 21f.

Specifically, the following compound semiconductors are grown on the Si substrate 1 by MOVPE, for example. Other method such as MBE may be used instead of MOVPE.

Compound semiconductors that will serve as the buffer layer 21a, electron transit layer 21b, the intermediate layer 21c, the electron donor layer 21d, the p-type cap layer 21e, and the n-type cap layer 21f are grown on the SiC substrate 1 in that order. The buffer layer 21a is formed by growing AlN on the Si substrate 1 to a thickness of approximately 0.1 μm. The electron transit layer 21b is formed by growing i-GaN to a thickness in the range of approximately 1 μm to approximately 3 μm. The intermediate layer 21c is formed by growing i-AlGaN to a thickness of approximately 5 nm. The donor layer 21d is formed by growing n-AlGaN to a thickness of approximately 30 nm. The intermediate layer 21c may be omitted. The electron donor layer may be formed of i-AlGaN.

The p-type cap layer 21e is formed by growing p-GaN to a thickness in the range of approximately 10 nm to approximately 1000 nm, for example. If the p-type cap layer 21e is thinner than nm, a desired 2DEG reduction effect cannot be achieved; if the p-type cap layer 21e is thicker than 1000 nm, 2DEG is so much reduced that the on-state resistance increases. Therefore, the p-type cap layer 21e is formed to a thickness in the range of approximately 10 nm to approximately 1000 nm to achieve an adequate 2DEG reduction effect while increase of the on-state resistance is minimized. In this embodiment, p-GaN of the p-type cap layer 21e is formed to a thickness of approximately 200 nm.

The n-type cap layer 21f is formed by growing n-GaN to a thickness in the range of approximately 5 nm to approximately 500 nm, for example, here to a thickness of approximately 100 nm, by taking into consideration the thickness of the p-type cap layer 21e.

To grow GaN, mixed gas of trimethyl gallium (TMGa) gas, which is the Ga source, and ammonium (NH₃) gas is used as material gas. To grow AlGaN, mixture gas of TMAl gas, TMGa gas and NH₃ gas is used as the material gas. Supplying and discontinuing supplying the TMAl and TMGa gases and the flow rates of the TMAl and TMGa gases are set as appropriate according to the compound semiconductor layer to grow. The flow rate of the NH₃ gas, which is a material common to the layers, is set to a value in the range of approximately 100 sccm to approximately 10 slm. The growth pressure is set to a value in the range of approximately 50 Torr to 300 Torr and the growth temperature is set to a value in the range of approximately 1000° C. to 1200° C.

When AlGaN and GaN are grown as the n-type, that is, when the electron donor layer 21d (n-AlGaN) and the n-type cap layer 21f (n-GaN) are formed, an n-type impurity is added to the material gasses of AlGaN and GaN. Here, for example silane (SiH₄) gas containing Si for example is added at a predetermined flow rate to the material gasses to dope AlGaN and GaN with Si. The doping concentration of Si is set to a value in the range of approximately 1×10¹⁸/cm³ to approximately 1×10²⁰/cm³, for example approximately 2×10¹⁸/cm³.

When GaN is grown as the p-type, that is, when the p-type cap layer 21e (p-GaN) is formed, a p-type impurity, for example an impurity selected between Mg and C, is added to the material gas of GaN. In this embodiment, Mg is used as the p-type impurity. Mg is added at a predetermined flow rate to the material gas to dope GaN with Mg. The doping concentration of Mg is in the range of approximately 1×10¹⁸/cm³ to approximately 1×10²¹/cm³, for example. If the doping concentration is less than approximately 1×10¹⁶/cm³, GaN is not sufficiently doped to p-type; if the doping concentration is greater than approximately 1×10²¹/cm³, imperfect crystallinity may result and sufficiently good characteristics cannot be provided. By choosing a Mg doping concentration in the range of approximately 1×10¹⁶/cm³ to approximately 1×10²¹/cm³, a p-type semiconductor that provides sufficiently good characteristics can be produced.

In the compound semiconductor multiplayer structure 21 thus formed, piezoelectric polarization is caused at the interface of the electron transit layer 21b with the electron donor layer 21d (to be exact, the interface with the intermediate layer 21c, which will be hereinafter referred to as the GaN/AlGaN interface) by a distortion due to the difference in lattice constant between GaN and AlGaN. The effect of the piezoelectric polarization in combination with the effect of spontaneous polarization in the electron transit layer 21b and the electron donor layer 21d produces two-dimensional electron gas (2DEG) with a high electron concentration at the GaN/AlGaN interface.

After the compound semiconductor multilayer structure 21 has been formed, the p-type cap layer 21e is annealed at approximately 700° C. for approximately 30 minutes.

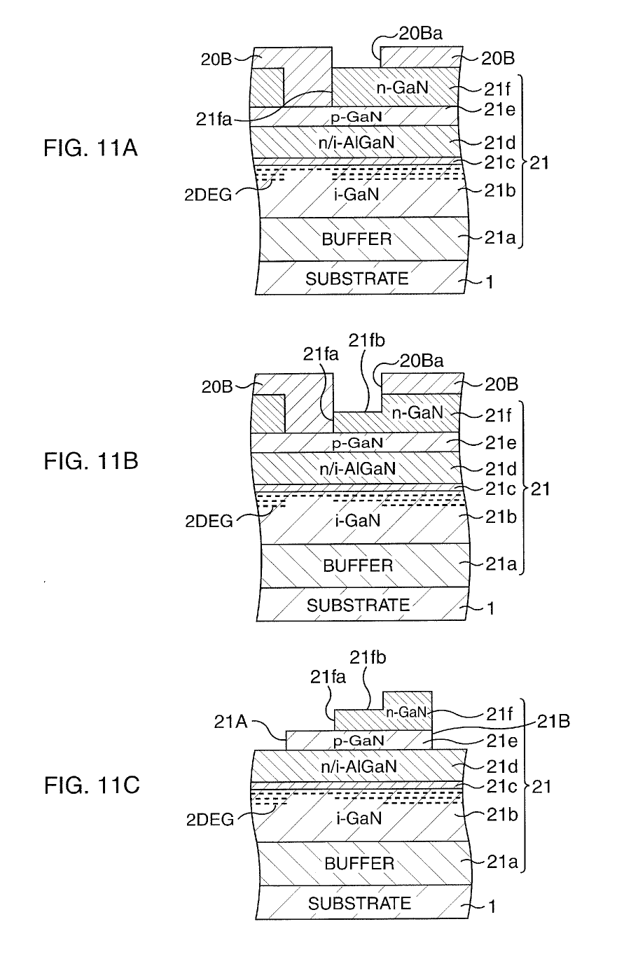

Then, as illustrated in FIGS. 10B to 11C, the n-type cap layer 21f is etched into a desired shape.

Specifically, as illustrated in FIG. 10B, first a resist is applied on the n-type cap layer 21f and lithography is used to process the n-type cap layer 21f. The result is a resist mask 20A having an opening 20Aa that exposes a predetermined region of the surface of the n-type cap layer 21f that is located closer to a location where a cathode electrode is to be formed than a location where an anode electrode is to be formed.

Then, the resist mask 20A is used to etch the n-type cap layer 21f by RIE using Cl₂ gas as the etching gas as illustrated in FIG. 100. As a result, an opening 21fa that exposes a predetermined region of the surface of the p-type cap layer 21e is formed in the n-type cap layer 21f.

The resist mask 20A is then removed by ashing or a wet process with a predetermined chemical.

In the compound semiconductor multilayer structure 21 in which the opening 21fa is formed in the n-type cap layer 21f, n-GaN of the n-type cap layer 21f does not exist in the opening 2fa. Accordingly, 2DEG in the region at the GaN/AlGaN interface that is located under the opening 21fa is almost depleted by p-GaN of the p-type cap layer 21e as illustrated. For example only a given small amount of 2DEG resides.

Then, a resist is applied on the n-type cap layer 21f so that the resist fills the opening 21fa, and then is processed by lithography as illustrated in FIG. 11A. As a result, a resist mask 20B having an opening 20Ba that exposes a predetermined region closer to a region where an anode electrode is to be formed, adjacent to the opening 21fa in the surface of the n-type cap layer 21f is formed.

Then, the resist mask 20B is used to etch the n-type cap layer 21f by RIE using Cl₂ gas as the etching gas as illustrated in FIG. 11B. As a result, a predetermined portion of the n-type cap layer 21f is thinned to a desired thickness. The thickness of the thinned portion 21fb is about the half of the thickness of the n-type cap layer 21f, for example approximately 50 nm, by taking into consideration desired control of the amount of 2DEG in the AlGaN/GaN diode.

In the compound semiconductor multilayer structure 21 in which the thinned portion 21fb is formed in the n-type cap layer 21f, n-GaN of the thinned portion 21fb is thinner than the rest of the n-type cap layer 21f (excluding the opening 21fa). Accordingly, 2DEG in the portion of the GaN/AlGaN interface that is located under the thinned portion 21fb is reduced by p-GaN of the p-type cap layer 21e by an amount according to the thinness of the thinned portion 21fb, as depicted.

The resist mask 20B is then removed by ashing or a wet process with a predetermined chemical.

Then, recesses 21A and 21B for the electrodes are formed in regions of the surface of the compound semiconductor multilayer structure 21 where a cathode electrode and an anode electrode are to be formed, as illustrated in FIG. 11C.

A resist mask is used to dry-etch the electrode formation regions of the n-type cap layer 21f and the p-type cap layer 21e to remove the n-type cap layer 21f and the p-type cap layer 21e from the electrode formation regions until the surface of the electron donor layer 21d is exposed. As a result, the electrode recesses 21A and 21B that expose the surface of the electron formation regions of the electron donor layer 21d are formed. At this point, the n-type cap layer 21f is left in a step form on the p-type cap layer 21e. The etching is performed using an inactive gas such as Ar and a chlorine-based gas such as Cl₂ as etch gasses. For example, Cl₂ is injected at a flow rate of 30 sccm and a pressure of 2 Pa with an RF input power of 20 W. The electrode recesses 21A and 21B may be formed by etching into the electron donor layer 21d and deeper.

The resist mask is then removed by ashing or a wet process with a predetermined chemical.

Thus, the n-type cap layer 21f is left in a step form on the p-type cap layer 21e. In the p-type cap layer 21e, 2DEG is modulated according to the thickness of the n-type cap layer 21f. That is, the concentration of 2DEG increases stepwise from the end of the p-type cap layer 21e on the electrode recess 21A side toward the end on the electrode recess 21B side. In this way, 2DEG is distributed so that the 2DEG concentration is lower on the cathode electrode side and is higher on the anode electrode side (2DEG is distributed so that the concentration of 2DEG gradually increases from the cathode electrode side to the anode electrode side), thereby implementing an AlGaN/GaN diode having a desired high withstand voltage.

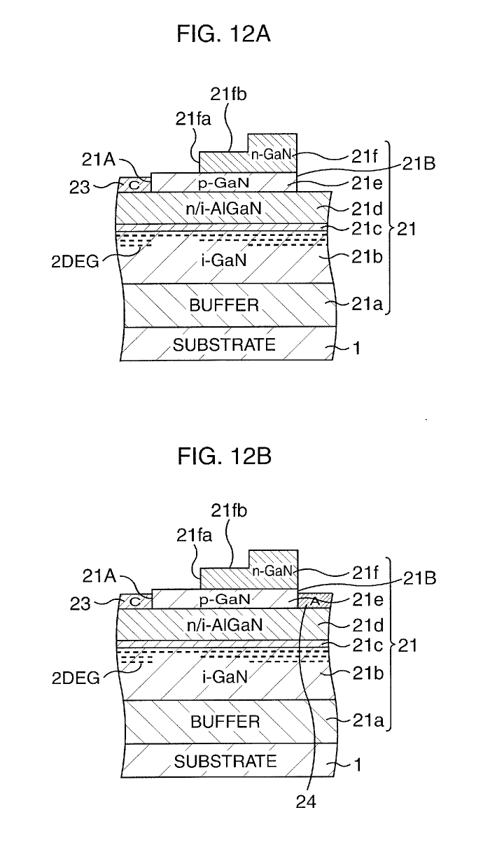

Then, a cathode electrode is formed as illustrated in FIG. 12A.

Specifically, a resist mask for forming the cathode electrode is formed first. Here, for example an overhanging double layer resist, which is suitable for vapor deposition and lift-off, is used. The resist is applied on the compound semiconductor multilayer structure 21 and an opening exposing the electrode recesses 21A is formed. In this way, a resist mask having the opening is formed.

An electrode material, for example Ta/Al is deposited on the resist mask, including the region inside the opening exposing the electrode recess 21A, by vapor deposition, for example. Ta is deposited to a thickness of approximately 20 nm; Al is deposited to a thickness of approximately 200 nm. The resist mask and Ta/Al deposited on the resist mask are removed by lift-off. In this way, the electrode recess 21A is filled with part of the electrode material to form a cathode electrode 23.

Then, anode electrode 24 is formed as illustrated in FIG. 12B.

Specifically, a resist mask for forming the anode electrode is formed first. Here, for example an overhanging double layer resist, which is suitable for vapor deposition and lift-off, is used. The resist is applied on the compound semiconductor multilayer structure 21 and an opening exposing the electrode recesses 21B is formed. In this way, a resist mask having the opening is formed.

An electrode material, for example Ni is deposited on the resist mask, including the region inside the opening exposing the electrode recess 21B, by vapor deposition, for example. Ni is deposited to a thickness of approximately 30 nm. The resist mask and Ni deposited on the resist mask are removed by lift-off. In this way, the electrode recess 21B is filled with part of the electrode material to form an anode electrode 24.

Thereafter, steps such as the steps of electrically connecting the cathode electrode 23 and the anode electrode 24 and forming the pads of the cathode electrode 23 and the anode electrode 24 to complete an AlGaN/GaN diode according to this embodiment.

In the AlGaN/GaN diode according to this embodiment, the n-type cap layer 21f on the p-type cap layer 21e is appropriately etched to control the concentration of 2DEG while the p-type cap layer 21e is left intact without etching the cap layer of p-GaN or regrowing p-GaN. In this way, the thickness of the n-type cap layer 21f is adjusted to effectively control the concentration of the p-type impurity (here, Mg) of the p-type cap layer 21e, thereby easily and reliably controlling the concentration of 2DEG while achieving a desired high withstand voltage.

Experiments conducted to investigate characteristics of the AlGaN/GaN diode according to this embodiment will be described below. As a comparative example, an AlGaN/GaN diode fabricated by growing p-GaN on an n-type cap layer of n-GaN, etching off unnecessary parts of p-GaN, then regrowing p-GaN with a different Mg concentration and performing whole thermal annealing is given.

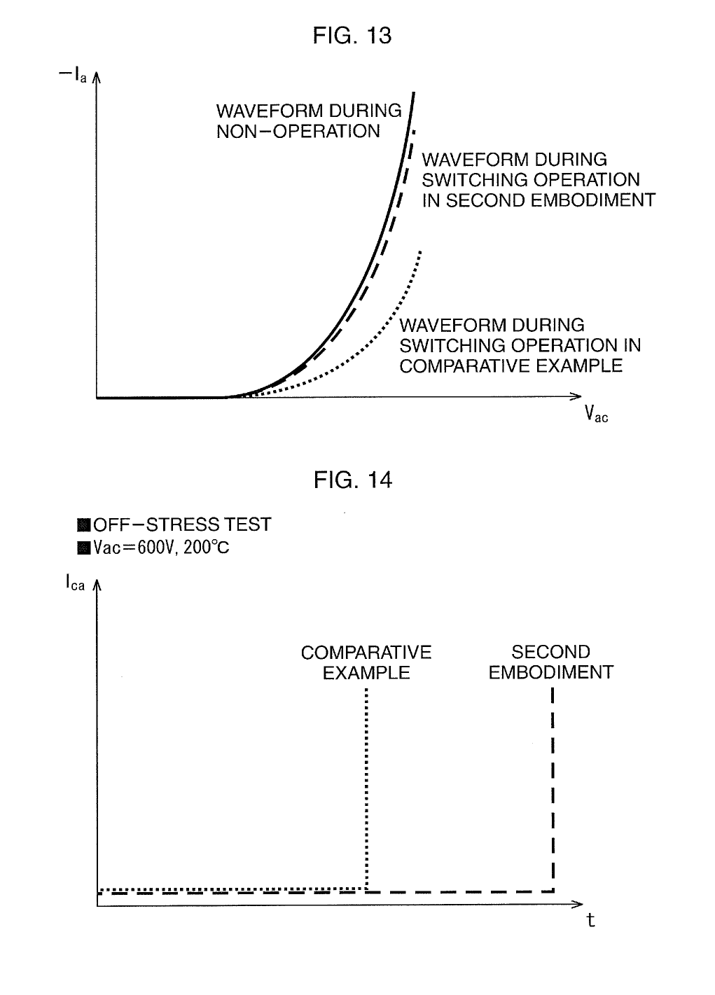

In experiment 1, the relationship between anode-cathode forward voltage Vac and anode current Ia was investigated. The results of the experiment are given in FIG. 13. In contrast to the comparative example, this embodiment shows a waveform during operation that is not much different from a waveform during non-operation. The results demonstrate that the present embodiment achieves a significant improvement in preventing reduction in current during operation as compared with the comparative example.

In experiment 2, a reverse voltage was continuously applied between the anode and cathode to determine the time that elapsed before breakdown. Here, Vac of 600 V was applied at a temperature of 200° C. FIG. 14 gives the results of the experiment. The results demonstrate that the time for breakdown to occur increases and the reliability of the device is improved in this embodiment as compared with the comparative example.

As has been described above, this embodiment implements a reliable, a high-withstand-voltage AlGaN/GaN diode in which the p-type cap layer 21e is used with the n-type cap layer 21f to minimize an increase in the on-state resistance during operation and not to regrow p-GaN during fabrication and the doping dose of the p-type impurity is in effect easily and reliably controlled to a predetermined value to enable a complex operation.

The AlGaN/GaN diode according to this embodiment is applicable to the so-called discrete package.

An AlGaN/GaN diode chip according to this embodiment is mounted on the discrete package. The discrete package of the AlGaN/GaN diode chip according to this embodiment (hereinafter referred to as the diode chip) will be described below.

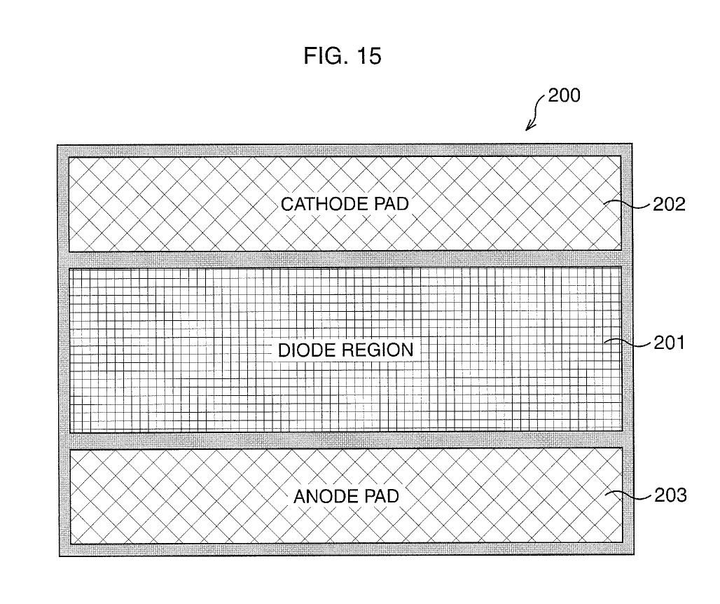

FIG. 15 schematically illustrates a configuration of the diode chip.

A diode region 201 of the AlGaN/GaN diode described above, a cathode pad 202 to which a cathode electrode is connected, and an anode pad 203 to which an anode electrode is connected are provided on a surface of the diode chip 200.

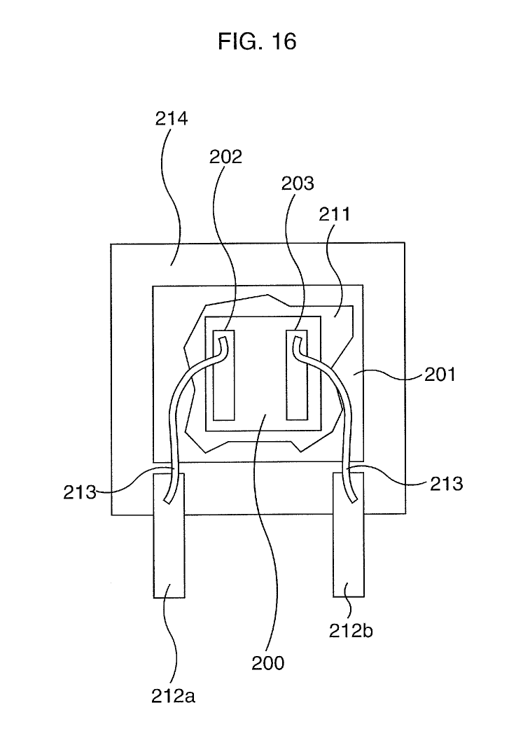

FIG. 16 is a schematic plan view of the discrete package.

To fabricate the discrete package, first the diode chip 200 is fixed to a lead frame 212 with a die attach paste 211 such as solder. A cathode lead 212a and an anode lead 212b are disposed separately and apart from the lead frame 212.

Then, bonding with Al wires 213 is performed to electrically connect the cathode pad 202 with the cathode lead 212a and the anode pad 203 with the anode lead 212b.

Thereafter, using a mold resin 214 the diode chip 200 is encapsulated with resin by transfer molding and the lead frame 212 is cut off. Thus, a discrete package is completed.

### Third Embodiment

In a third embodiment, a Power Factor Correction (PFC) circuit including an AlGaN/GaN HEMT according to the first embodiment and/or an AlGaN/GaN diode according to the second embodiment will be disclosed.

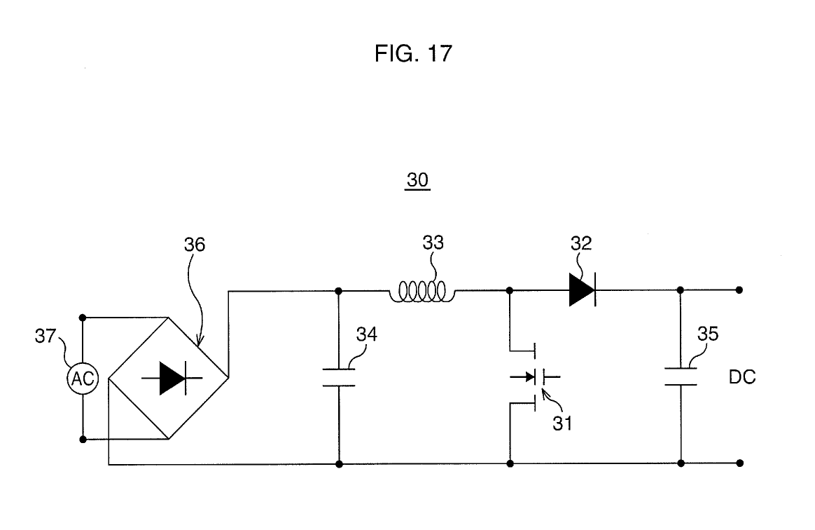

FIG. 17 is a connection diagram of the PFC circuit.

The PFC circuit 30 includes a switch element (transistor) 31, a diode 32, a choke coil 33, capacitors 34, 35, a diode bridge 36, an alternating-current power supply (AC) 37. An AlGaN/GaN HEMT according to the first embodiment is applied to the switch element 31. Alternatively, an AlGaN/GaN diode according to the second embodiment is applied to the diode 32. Alternatively, an AlGaN/GaN HEMT according to the first embodiment is applied to the switch element 31 and an AlGaN/GaN diode according to the second embodiment is applied to the diode 32. An AlGaN/GaN diode according to the second embodiment may also be applied to the diode bridge 36.

In the PFC circuit 30, a drain electrode of the switch element 31, an anode terminal of the diode 32, and one terminal of the choke coil 33 are connected together. A source electrode of the switch element 31, one terminal of the capacitor 34, and one terminal of the capacitor 35 are connected together. The other terminal of the capacitor 34 and the other terminal of the choke coil 33 are connected together. The other terminal of the capacitor 35 and a cathode terminal of the diode 32 are connected together. The AC 37 is connected between both terminals of the capacitor 34 through a diode bridge 36. A direct-current power supply (DC) is connected between both terminals of the capacitor 35. A PFC controller, not depicted, is connected to the switch element 31.

In this embodiment, the AlGaN/GaN HEMT according to the first embodiment and/or the AlGaN/GaN diode according to the second embodiment is applied to the PFC circuit 30. This implements a highly reliable PFC circuit 30.

### Fourth Embodiment

In a fourth embodiment, a power supply device including AlGaN/GaN HEMTs according to the first embodiment and an AlGaN/GaN diode according to the second embodiment will be disclosed.

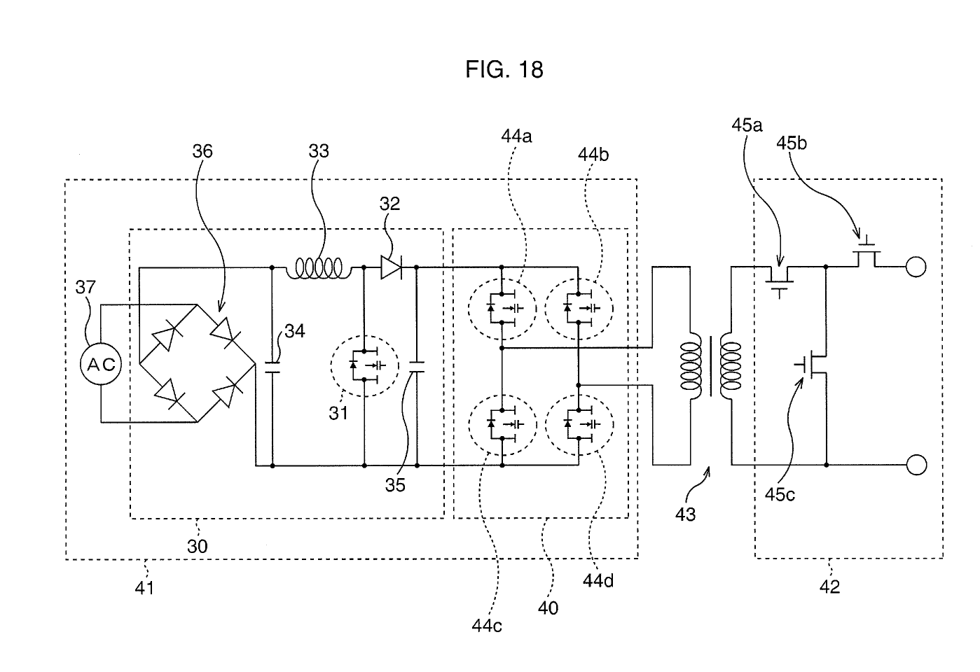

FIG. 18 is a connection diagram schematically illustrating a configuration of the power supply device according to the fourth embodiment.

The power supply device according to this embodiment includes a high-voltage primary circuit 41, a low-voltage secondary circuit 42, and a transformer disposed between the primary circuit 41 and the secondary circuit 42.

The primary circuit 41 includes a PFC circuit 30 according to the third embodiment, an inverter circuit, for example a full-bridge inverter circuit 40, connected between both terminals of a capacitor of the PFC circuit 30. The full-bridge inverter circuit 40 includes a plurality of (four in this example) switch elements 44a, 44b, 44c and 44d.

The secondary circuit 42 includes a plurality of (three in this example) switch elements 45a, 45b and 45c.

In this embodiment, the PFC circuit of the primary circuit 41 is a PFC circuit 30 according to the third embodiment and the switch elements 44a, 44b, 44c and 44d of the full-bridge inverter circuit 40 are AlGaN/GaN HEMTs according to the first embodiment. The switch elements 45a, 45b and 45c of the secondary circuit 42, on the other hand, are conventional silicon-based MIS FETs.

In an AlGaN/GaN HEMT according to one selected from among the first embodiment and variations thereof, a p-n junction is formed under the field-plate electrode as described with respect to the first embodiment. This provides the function of a protection diode in which the field-plate electrode serves as the anode and the drain electrode serves as the cathode. In this embodiment, the AlGaN/GaN HEMTs are applied to the switch element 31 of the PFC circuit 30 and the switch elements 44a, 44b, 44c and 44d of the full-bridge inverter circuit 40. Therefore, the rectification effect of the protection diode prevents breakdown of the switch elements 31, 44a, 44b, 44c and 44d in the primary circuit 41 if a surge voltage is generated in the switch elements 31, 44a, 44b, 44c and 44d. In this way, high avalanche resistance is ensured to contribute to stabilization of device operations.

In this embodiment, the PFC circuit 30 according to the third embodiment, the AlGaN/GaN HEMTs according to the first embodiments, and the AlGaN/GaN diode according to the second embodiment are applied to the primary circuit 41, which is a high-voltage circuit. This implements a reliable, high-power power supply device.

### Fifth Embodiment

In a fifth embodiment, a high-frequency amplifier including an AlGaN/GaN HEMT according to the first embodiment will be disclosed.

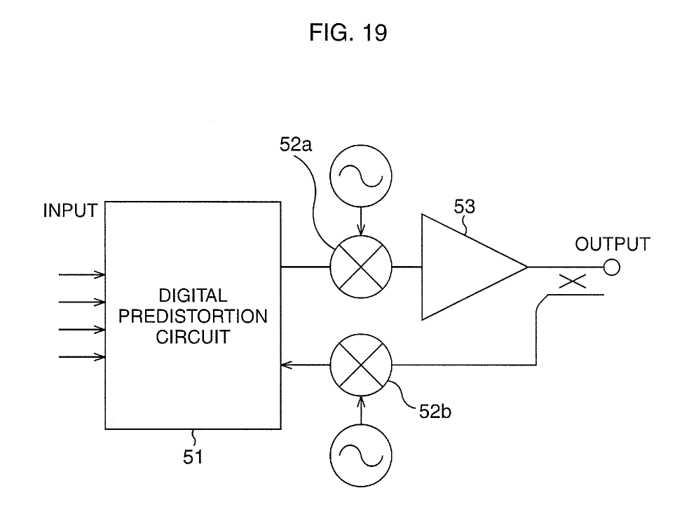

FIG. 19 is a connection diagram schematically illustrating a configuration of the high-frequency amplifier according to the fifth embodiment.

The high-frequency amplifier according to this embodiment includes a digital predistortion circuit 51, mixers 52a and 52b and a power amplifier 53.

The digital predistortion circuit 51 compensates for nonlinear distortion of an input signal. The mixer 52a mixes an input signal whose linear distortion has been compensated for with an AC signal. The power amplifier 53 amplifies an input signal mixed with an AC signal and includes an AlGaN/GaN HEMT according to the first embodiment. It is noted that in FIG. 19, a switching operation of a switch, for example, enables an output signal to be mixed with the AC signal at the mixer 52b and sent back to the digital predistortion circuit 51.

In this embodiment, the AlGaN/GaN HEMTs according to the first and second embodiment is applied to a high-frequency amplifier. This implements a highly reliable high-frequency amplifier having a high withstand voltage.

### Alternative Embodiments

A compound semiconductor device has been described in the first embodiment by taking an AlGaN/GaN HEMT as an example. The compound semiconductor device can also be applied to other HEMTs such as those described below in addition to the AlGaN/GaN HEMT.

A compound semiconductor device that is an AlGaN/GaN diode has been illustrated in the second embodiment. The compound semiconductor device can be applied to other diodes such as those described below as well, in addition to AlGaN/GaN diodes.

### Alternative Exemplary Device 1

In this example, an InAlN/GaN HEMT and an InAlN/GaN diode will be disclosed as compound semiconductor devices.

InAlN and GaN are compound semiconductors that have lattice constants that can be made closer to each other by adjusting the composition ratios. In this case, the electron transit layer in the first and second embodiments described above is made of i-GaN, the intermediate layer is made of AlN, the electron donor layer is made of n-InAlN, the p-type cap layer is made of p-GaN, and the n-type cap layer is made of n-GaN. Also in this case, little piezoelectric polarization not occurs and therefore two-dimensional electron gas is produced primarily by spontaneous polarization of InAlN.

This example implements a highly reliable, high-withstand-voltage InAlN/GaN HEMT and InAlN/GaN diode in which, like the AlGaN/GaN HEMT and AlGaN/GaN diode described above, an n-type compound semiconductor layer is used together with a p-type compound semiconductor layer and the dose of a p-type dopant is in effect easily and reliably controlled to a predetermined value to enable a complex operation without regrowing the compound semiconductor layers.

### Alternative Exemplary Device 2

In this exemplary embodiment, an InAlGaN/GaN HEMT and an InAlGaN/GaN diode will be disclosed as compound semiconductor devices.

GaN and InAlGaN are compound semiconductors and the lattice constant of the latter can be made smaller than that of the former by adjusting the composition ratio. In this case, the electron transit layer in the first and second embodiments described above is made of i-GaN, the intermediate layer is made of i-InAlGaN, the electron donor layer is made of n-InAlGaN, the p-type cap layer is made of p-GaN, and the n-type cap layer is made of n-GaN.

This example implements a highly reliable, high-withstand-voltage InAlGaN/GaN HEMT and InAlGaN/GaN diode in which, like the AlGaN/GaN HEMT and AlGaN/GaN diode described above, an n-type compound semiconductor layer is used together with a p-type compound semiconductor layer and the dose of a p-type dopant is in effect easily and reliably controlled to a predetermined value to enable a complex operation without regrowing the compound semiconductor layers.

The modes described above implement reliable high-withstand-voltage compound semiconductor device and a method for fabricating such compound conductor device in which a first compound semiconductor layer having a first polarity is used together with a second compound semiconductor having the polarity (a second polarity) opposite the first polarity and the dose of a dopant of a conductivity type corresponding to the second polarity is in effect easily and reliably controlled to a desired value to enable a complex operation without regrowing the compound semiconductor layers.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device comprising:
a first compound semiconductor layer comprising a first polarity;
a second compound semiconductor layer formed above the first compound semiconductor layer, the second compound semiconductor layer comprising a second polarity; and
a third compound semiconductor formed above the second compound semiconductor layer, the third compound semiconductor layer comprising the first polarity;
wherein the third compound semiconductor layer comprises a portion comprising a different thickness.

2. The compound semiconductor device according to claim 1, wherein the first polarity is negative.

3. The compound semiconductor device according to claim 1, wherein a through-opening is formed in the third compound semiconductor layer; and
the compound semiconductor device further comprises a gate electrode which fills the through-opening.

4. The compound semiconductor device according to claim 1, further comprising a field-plate electrode formed on the third compound semiconductor layer.

5. The compound semiconductor device according to claim 4, wherein the field-plate electrode is formed on a thin portion of the third compound semiconductor layer.

6. The compound semiconductor device according to claim 1, further comprising a pair of electrodes formed above the first compound semiconductor layer, the pair of electrodes being on both sides of the third compound semiconductor layer;
wherein a portion of the third compound semiconductor layer that is closer to one of the electrodes is formed thinner than a portion of the third compound semiconductor that is closer to the other electrode.

7. A method for fabricating a compound semiconductor device, the method comprising:
forming a first compound semiconductor layer comprising a first polarity;
forming a second compound semiconductor layer above the first compound semiconductor layer, the second compound semiconductor layer comprising a second polarity;
forming a third compound semiconductor layer above the second compound semiconductor layer, the third compound semiconductor layer comprising the second polarity; and
forming a portion comprising a different thickness in the third compound semiconductor layer.

8. The method for fabricating a compound semiconductor device according to claim 7, wherein the first polarity is negative.

9. The method for fabricating a compound semiconductor device according to the claim 7, further comprising:
forming a through-opening in the third compound semiconductor layer; and
forming a gate electrode filling the through-opening.

10. The method for fabricating a compound semiconductor device according to claim 7, further comprising forming a field-plate electrode on the third compound semiconductor layer.

11. The method for fabricating a compound semiconductor device according to claim 10, wherein the field-plate electrode is formed on a thin portion of the third compound semiconductor layer.

12. The method for fabricating a compound semiconductor device according to claim 7, further comprising forming a pair of electrodes above the first compound semiconductor layer, the pair of electrodes being on both sides of the third compound semiconductor layer;
wherein a portion of the third compound semiconductor that is closer to one of the electrodes is formed thinner than a portion of the third compound semiconductor that is closer to the other electrode.

13. A power supply device comprising a transformer, and a high-voltage circuit and a low-voltage circuit disposed with the transformer between the high-voltage and the low-voltage circuits,
the high-voltage circuit comprising a transistor and a diode, one of the transistor and the diode or both of the transistor and the diode comprising:
a first compound semiconductor layer comprising a first polarity;
a second compound semiconductor layer formed above the first compound semiconductor layer, the second compound semiconductor layer comprising a second polarity; and
a third compound semiconductor layer formed above the second compound semiconductor layer, the third compound semiconductor layer comprising the first polarity;
wherein the third compound semiconductor layer comprises a portion comprising a different thickness.
